(19) United States
(12) Patent Application Publication
(10) Pub. No.: US 2006/0109027 A1
(43) Pub. Date: May 25, 2006

(54) Programmable logic cell

(76) Inventor: Francisco Javier Veredas-Ramirez, Munchen (DE)

Correspondence Address: BRINKS HOFER GILSON & LIONE;INFINEON, PO BOX 10395, CHICAGO, IL, 60610, US

(21) Appl. No.: 11/284,697

(22) Filed: Nov. 21, 2005

(30) Foreign Application Priority Data
Nov. 24, 2004 (DE) 10 2004 056 738.7

(51) Int. Cl. H03K 19/173; G06F 7/38

(52) U.S. Cl. 326/37

(57) ABSTRACT

For a programmable logic cell, an output assumes a value, which is dependent on values of inputs and on a Boolean function, which determines a value for the output for each setting of the inputs. The logic cell includes at least one ALU and additional logic via which the Boolean function of the logic cell is configurable. In a preferred embodiment, the logic cell contains two 1-bit ALUs and a block generator with four configuration bit memory cells. Here the logic cell can be configured in such a way that it replicates any desired Boolean function with four parameters or any two Boolean functions with two parameters, or is operated in an arithmetic mode.

### PRIORITY AND CROSS REFERENCE TO RELATED APPLICATION

This application claims priority to German Patent Application No. 10 2004 056 738.7, filed Nov. 24, 2004, which is incorporated in its entirety herein by reference.

### BACKGROUND OF THE INVENTION

1. Field of the Invention

The present invention relates to a programmable logic cell, which can be used in programmable logic arrays, programmable arithmetic units or with programmable digital circuit arrangements, which are configurable either as a programmable logic array or as a programmable arithmetic unit.

2. Description of the Related Art

Programmable logic arrays are typically generic and very regular architectures for logical operations. A programmable logic array includes only a few types of configurable cells:
logic cells
signal input cells
signal output cells
switch matrix cells
input/output pins

Here logic cells execute signal processing on the bit level. Signal input cells receive a signal e.g. from an interconnect bug, the signal being forwarded to an input of a logic cell. A signal output cell forwards an output signal of a logic cell e.g. to a bus. Switch matrix cells enable any paths in an interconnecting network of the logic array. Input/output pins connect the programmable logic array to the outside world.

Programmable logic arrays include a large number of switches, which are controlled by configuration bits, enabling a large number of signal paths to be set. This means that a certain function of a programmable logic array is defined by its configuration bits, which are usually stored in configuration bit memory cells. Particularly for a field-programmable logic array (FPGA), the number of configuration bits is high. Typical FPGA structures need about 200 bits per logic cell (including a calculated segment of the configurable connections). A chain of configuration bits forms a configuration word of several Mbits, the precise size depending on the complexity of the FPGA.

Configurable logic cells according to prior art include a look-up table (LUT), in order to implement a Boolean function from N inputs and one output. Such a logic cell 100 according to prior art is shown in FIG. 1. The logic cell 100 contains an LUT 201 with four inputs and one output, the output being switched via a multiplexer 203, directly configurable or via a flip-flop 202, to the output of the logic cell. An advantage of an LUT is that every theoretically feasible mapping can be implemented between the inputs and the output of the LUT.

FIG. 2 represents an LUT 201 in detail. The LUT 201 includes 16 configuration bit memory cells 300, which are switched via multiplexers 301 to the output of the LUT 201. A selection is made here of which configuration bit memory cell 300 is switched to the output of the LUT 201, via the four inputs A-D, which simultaneously control the multiplexers 301. Any desired Boolean function f(A, B, C, D) is configurable with the LUT 201.

With N parameters, the number of different Boolean functions is 2 raised to the power 2^{N}. Since the Boolean function implemented by the LUT 201 in FIG. 2 has four parameters (A-D), the number of user-defined functions that the LUT must be capable of implementing is 2 to the power 2⁴=2¹⁶=65536. This is also possible, since the 16 configuration bit memory cells, which can each be set to 0 or 1, can be set in 2¹⁶=65536 different ways.

FIG. 3 represents a programmable arithmetic unit 100a according to prior art. The programmable arithmetic unit 100a includes a 1-bit ALU 501 and control logic 500, as well as an output logic 202, 203 as previously explained for FIG. 1. The programmable arithmetic unit 100a links values present at the two inputs of the programmable arithmetic unit 100a with the help of the 1-bit ALU 501, the control logic 500 being used to configure which arithmetic operation links the two input values.

With an FPGA too, arithmetical logical functions can be implemented with the help of LUTs and corresponding additional logic. However, the additional logic requires a large proportion of the area of the FPGA. Furthermore, in comparison to an ALU the FPGA has long time delays and an increased power requirement. This means that an FPGA or a logic cell, which is used for performing arithmetic functions, has disadvantages compared to an ALU with regard to the space required, the delay time and the power consumption. This is mainly because a significant part of an area needed by a universally usable logic cell according to prior art is needed for switching sections of the logic cell, which are not used in arithmetic functions.

Accordingly, there is a need to provide a logic cell, a programmable logic array, a programmable arithmetic unit and/or a programmable digital circuit arrangement that is configurable as a programmable logic array or as a programmable arithmetic unit, without at least some of the previously described disadvantages, and reducing a number of configuration bits or configuration bit memory cells in comparison to prior art.

### SUMMARY OF THE INVENTION

The present invention relates to a programmable logic cell for a programmable digital circuit arrangement. The logic cell may include at least one ALU and an additional logic or additional logic circuit, and is developed in such a way that a value at the output of the logic cell has a functional value of a Boolean function. Parameters of the Boolean function correspond to values of inputs to the logic cell. The inputs to the logic cell are connected to inputs of the ALU and outputs of the ALU are connected via the additional logic to the output of the logic cell. The Boolean function of the logic cell is configurable via the additional logic. Since the logic cell according to the invention includes at least one ALU, arithmetic functions of the logic cell can be processed with a shorter delay time than with a logic cell according to prior art.

In an embodiment, the logic cell can replicate any desired Boolean function with N parameters, where N is the number of inputs of the logic cell.

Consequently, the logic cell can be used according to the invention without restriction as a look up table (LUT) on the one hand, and in an arithmetic mode on the other hand.

In another embodiment, the logic cell can only replicate, or implement, any desired function with N parameters (N =number of inputs of the logic cell) if the order of the inputs can be predefined or the inputs can be permutated, and/or if a part or all inputs are selected by the additional logic inverted or not inverted in each case.

By the presetting of the order of the inputs, the number of Boolean functions to be implemented by the logic cell according to the invention is greatly reduced. Here the possibility of feeding each input (or only a part of the inputs) by means of the additional logic to a remainder of the logic cell, inverted or not inverted in each case, further reduces the number of Boolean functions to be implemented by the remainder of the logic cell, i.e. the presetting of the order and the option of configuring inversion of the inputs is advantageously complementary.

In a further embodiment, the logic cell has four inputs and at least one ALU having two 1-bit ALUs. Here the Boolean function can be configured via the additional logic in such a way that it can be any desired Boolean function with four parameters. Two of the four inputs of the logic cell are connected to inputs of one of the two 1-bit ALUs in each case here. At least one of the two 1-bit ALUs can be developed such that its output assumes a value of a further Boolean function, the parameters of the Boolean function being the two inputs of this 1-bit ALU. This Boolean function can be configured via the additional logic, i.e. this 1-bit ALU is able to form any theoretically feasible Boolean function for two parameters.

Since one or both 1-bit ALUs can form any theoretically feasible Boolean function for two parameters, a large proportion of all possible Boolean functions for four parameters is advantageously already covered by the 1-bit ALUs, so that the additional logic becomes correspondingly space-saving.

According to the invention, one or both of the 1-bit ALUs can be developed such that it can only implement every theoretically feasible Boolean function for two parameters if an order can be predefined for its two inputs.

For two inputs, there are two possible orders (a,b or b,a). It can be shown that the 1-bit ALU need only be able to implement 12 of 16 possible Boolean functions with two parameters, if the order of the inputs can be predefined. This is also termed permutability of the inputs. The 1-bit ALU can then be implemented in a more compact form, i.e. with fewer gates or with a reduced space requirement. Furthermore, one or both inputs of the 1-bit ALU can be configurable by the additional logic as inverted or not inverted.

This measure also advantageously (further) reduces the number of Boolean functions that the 1-bit ALU has to implement, so that the 1-bit ALU can again be executed in a more compact form. If only one input of the 1-bit ALU can be inverted by configuration and the inputs can be permutated, the number of Boolean functions with two parameters to be implemented by the 1-bit ALU is reduced to 9. If both inputs of the 1-bit ALU can be inverted by configuration and the inputs can be permutated, the number of Boolean functions with two parameters to be implemented by the 1-bit ALU is actually reduced to 7.

It can be pointed out here that a more compact 1-bit ALU also has a lower energy consumption than a less compact 1-bit ALU. Furthermore, a delay time of a more compact 1-bit ALU is generally shorter in comparison to a less compact 1-bit ALU. The more compact the two 1-bit ALUs are in construction, the more compact is also the construction of the logic cell according to the invention. The logic cell according to the invention therefore also has the same advantages as the 1-bit ALUs with regard to the runtime, the space required and the energy consumption compared to a logic cell according to prior art.

Also provided within the scope of the present invention are a programmable logic array, a programmable arithmetic unit and a programmable digital circuit arrangement which is configurable as a programmable logic array or as a programmable arithmetic unit, each of these including at least one logic cell according to the invention.

Since according to the invention the programmable logic array, the programmable arithmetic unit and the programmable digital circuit arrangement each include at least one logic cell according to the invention, they have advantages just as the logic cell with regard to the delay time, the space required and the energy consumption compared to programmable logic array, programmable arithmetic units and programmable digital circuit arrangement according to prior art.

### DESCRIPTION OF THE DRAWINGS

The present invention will be further described with reference to the attached drawing on the basis of preferred embodiments.

FIG. 1 represents a logic cell with a look-up table (LUT).

FIG. 2 represents the look-up table (LUT) of FIG. 1.

FIG. 3 represents a programmable arithmetic unit. 100291 FIG. 4 represents a first embodiment according to the invention with a logic cell with a block generator and two 1-bit ALUs.

FIG. 5 represents a representation of the block generator of FIG. 4.

FIG. 6 represents a representation of a further variant of the block generator of FIG. 4.

FIG. 7 represents a 1-bit ALU, such as can be used in the first embodiment of the logic cell.

FIG. 8 represents a decoder circuit, which can be part of a logic cell according to the invention.

FIG. 9 represents a variant of a 1-bit ALU, such as can be used in the first embodiment of the logic cell.

FIG. 10 represents a second embodiment of the logic cell according to the invention.

FIG. 11 represents a 1-bit ALU, such as can be used in the second embodiment of the logic cell.

FIG. 12 represents a third embodiment of the logic cell according to the invention.

FIG. 13 represents a 1-bit ALU, such as can be used in the third embodiment of the logic cell.

FIG. 14 represents a fourth embodiment of the logic cell according to the invention.

FIG. 15 shows a programmable logic array according to the invention, which uses four logic cells of FIG. 4.

FIG. 16 represents a programmable arithmetic unit according to the invention, which uses four logic cells of FIG. 4.

FIG. 17 represents a programmable digital circuit arrangement according to the invention, which is configurable as a programmable logic array or as a programmable arithmetic unit and uses four logic cells of FIG. 4.

### DESCRIPTION OF THE PREFERRED EMBODIMENTS

Identical, functionally identical, or similar elements and signals are referred to with the same reference symbols in the figures unless stated otherwise.

FIG. 4 shows a first embodiment of a logic cell 100b. The logic cell 100b has four inputs 609a-d and two outputs 608a-b. Each input 609a-d is fed to a selection inversion logic 601, 602, which includes in each case of an inverter 601 and a multiplexer 602 and ensures that the respective input 609a-d is fed to a remainder of the logic cell 100b via an additional logic (not shown) of the logic cell 100b, configurably inverted or not inverted. The two inputs 609a-b are fed inverted or not inverted to a first (in FIG. 4 above) 1-bit ALU 603 while via the additional logic with the help of two multiplexers 618 it is configurable whether the inputs 609a-b or the inputs 609c-d are fed inverted or not inverted to a second (in FIG. 4 below) 1-bit ALU 603. A block generator 604 has six inputs 610-615 and one output 616. The six inputs 610-615 are made up of one output 610 from the first 1-bit ALU, one output 611 from the second 1-bit ALU and the four outputs 612-615 from the multiplexers 602 of the selection inversion logics of the four inputs 609a-d of the logic cell 100b. Via a multiplexer 606 it is configurable with the additional logic whether the output 610 of the first 1-bit ALU or the output 616 of the block generator 604 is fed to the output 608a buffered over a flip-flop 617. It is similarly configurable via a multiplexer 607 with the additional logic whether the output 611 of the second 1-bit ALU buffered over a flip-flop 617 or the output 616 of the block generator 604 is fed to the output 608b. Among other things, it is thereby controlled via the two multiplexers 606, 607 whether the logic cell 100b is operated in the mode for an arithmetic logical unit or in the mode for an FPGA.

Since the two multiplexers 618 before the second 1-bit ALU are controlled by one configuration signal, only seven control signals are needed for controlling the eight multiplexers 602 (×4), 606, 607, 618 (×2). The presented logic cell 100b can be operated, or configured, either as one programmable 4-bit logic cell for one FPGA, as two programmable 2-bit logic cells for one FPGA or as two independent 1-bit ALUs. In the configuration as a programmable 4-bit logic cell for an FPGA, the logic cell 100b replicates a look-up table (LUT) with four inputs and one output, while in the configuration as two programmable 2-bit logic cells for an FPGA it replicates two look-up tables (LUTs) each with two inputs and one output.

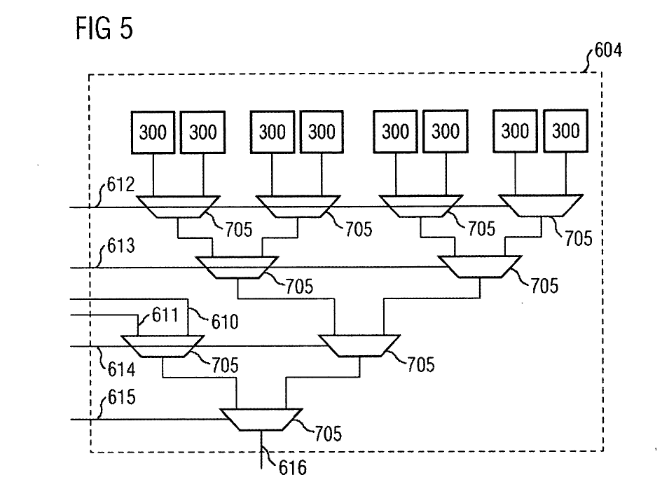

FIG. 5 represents the block generator 604 shown in FIG. 4. The block generator 604 is necessary if the logic cell 100b is used as a programmable 4-bit logic cell for an FPGA and all possible Boolean functions with four parameters can be implemented with it. The block generator 604 shown in FIG. 5 contains eight configuration bit memory cells 300 and four rows of multiplexers 705, which are controlled via the inputs 612-615 derived from the inputs 609a-d of the logic cell 100b. Via the inputs 612-615 it is controlled whether a configuration bit memory cell 300 (and also which one) or an output 610, 611 of the two 1-bit ALUs is switched to the output 616 of the block generator 604.

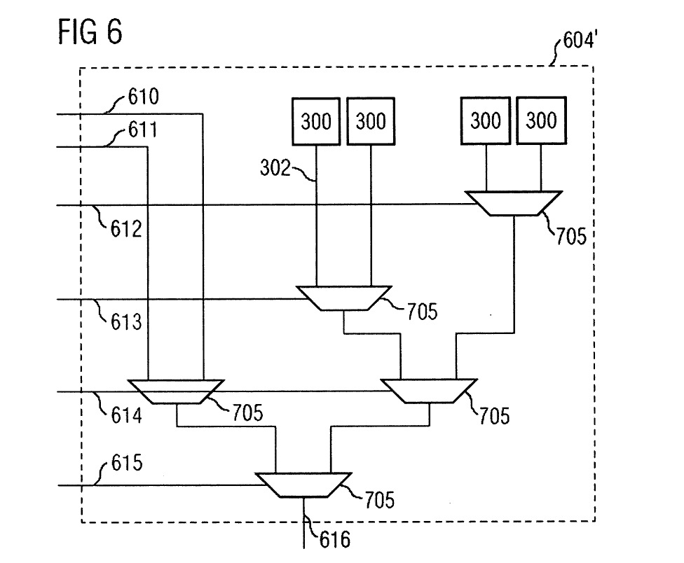

It has been shown that instead of the block generator 604 shown in FIG. 5 with eight configuration bit memory cells 300, a block generator 604′ shown in FIG. 6 with only four configuration bit memory cells 300 can also be used, without the function of an FPGA which uses logic cells with the block generator 604′ shown in FIG. 6 falling behind the function of an FPGA which uses logic cells with the block generator 604 shown in FIG. 5. It can be proved that with the logic cell 100b with the block generator 604′ shown in FIG. 6, 2¹⁵ Boolean functions with four parameters are configurable, while theoretically 2¹⁶ Boolean functions with four parameters exist, as previously explained. It can further be proved that the 2¹⁵ Boolean functions with four parameters are sufficient for the present-day heuristic synthesis tools for creating any desired combinational circuit, which can also be created with logic cells which can generate all 2¹⁶ Boolean functions with four parameters.

The block generator 604′ shown in FIG. 6 works in principle in exactly the same way as the block generator 604 shown in FIG. 5, i.e. the inputs 612-615 control whether one of the four configuration bit memory cells 300 or the output 610 of the first 1-bit ALU or the output 611 of the second 1-bit ALU is switched to the output 616 of the block generator 604′.

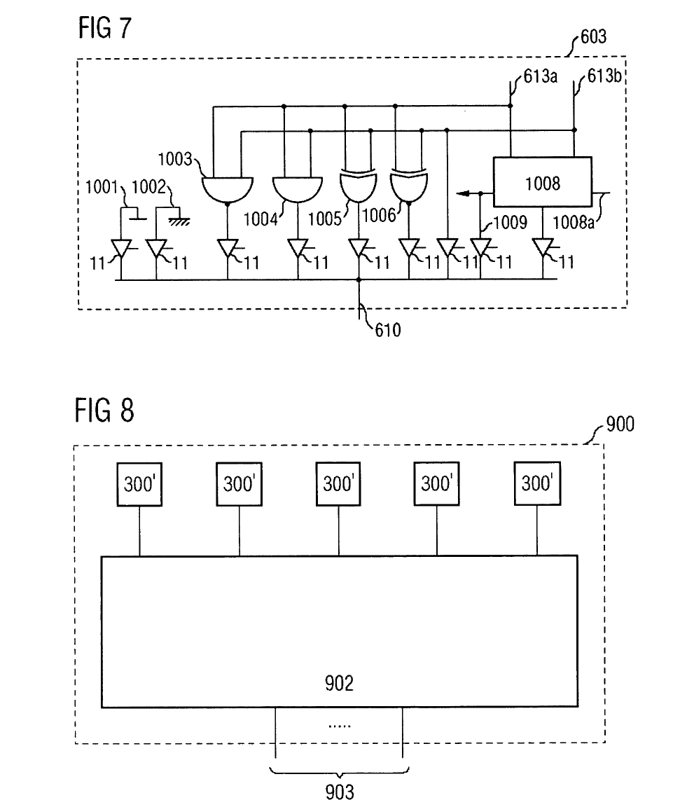

In FIG. 7, one of the 1-bit ALUs 603 used by the logic cell 100b is represented in detail. The 1-bit ALU 603 contains a NAND gate 1003, an AND gate 1004, an XOR gate 1005, an XNOR gate 1006 and a full adder 1008. The inputs 613a-b of the 1-bit ALU 603 are applied to the NAND gate 1003, the AND gate 1004, the XOR gate 1005, the XNOR gate 1006 and the full adder 1008. Every output of the NAND gate 1003, the AND gate 1004, the XOR gate 1005, the XNOR gate 1006 and the full adder 1008 are switched together with the input 613b and a logical “1” 1001, and a logical “0” 1002 over tri-state drivers 11 to the output 610 of the 1-bit ALU 603. In each case, only one of the tri-state drivers 11 is switched through, while all other tri-state drivers 11 are switched to a high resistance.

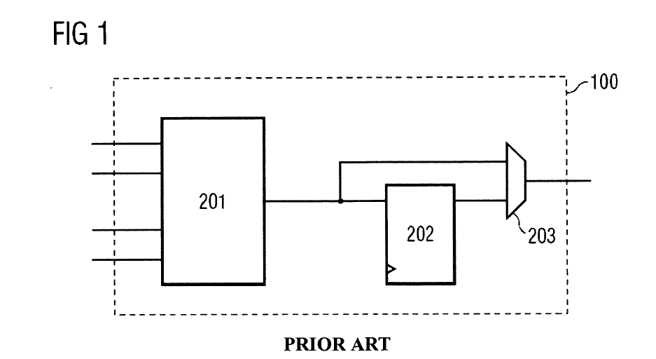

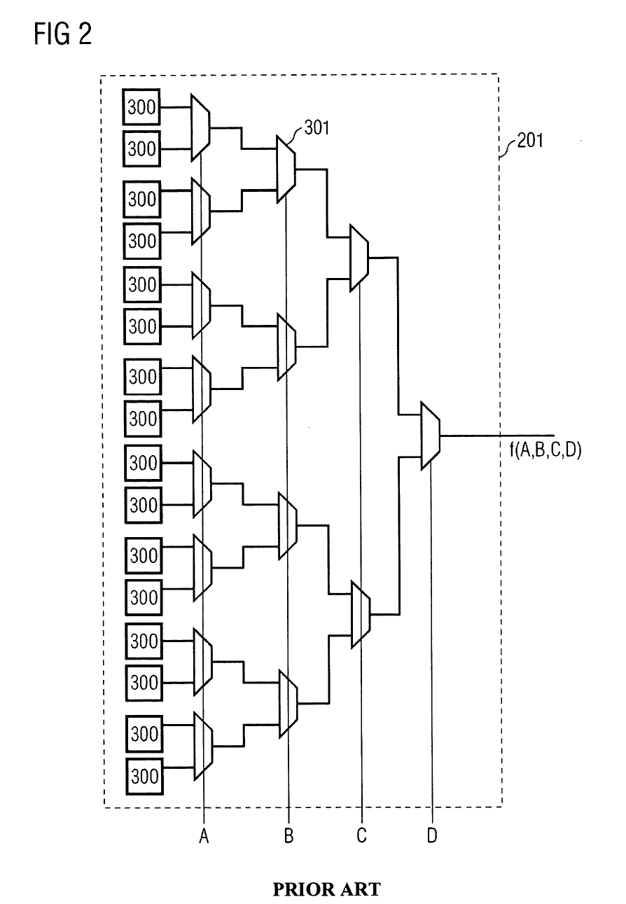

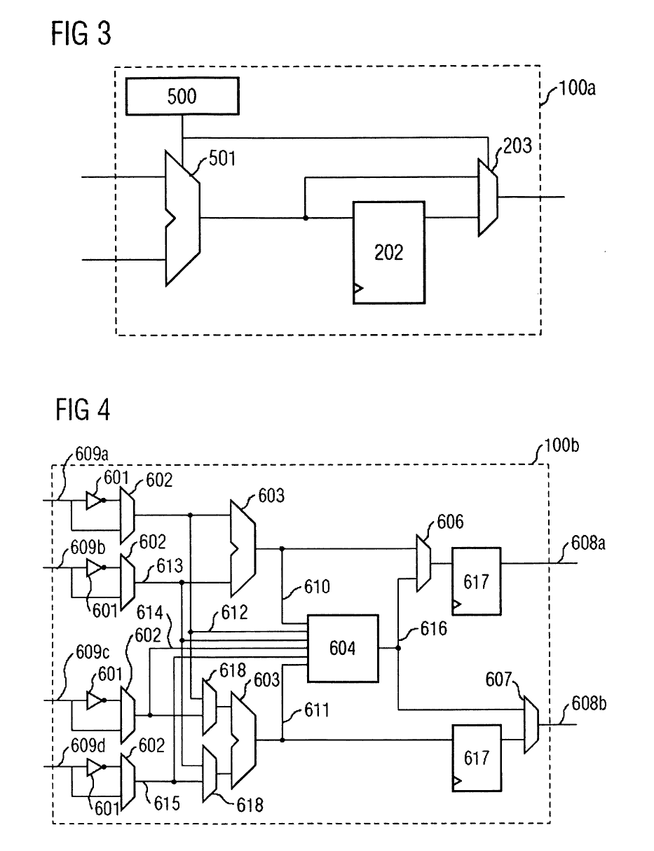

For the configuration of the 1-bit ALU 603, nine configuration signals may be used to control the nine tri-state drivers 11 shown in FIG. 7. Together with the seven configuration signals described in connection with FIG. 4 for the configuration of the multiplexers shown in FIG. 4, the total thus amounts to 25 configuration signals. However, far fewer than the 2²⁵ configurations possible with the 25 configuration signals are meaningful. For example, for the nine configuration signals of the 1-bit ALU 603 only nine configurations are meaningful (exactly one of the nine tri-state drivers 11 is switched through). It can be proved that the number of meaningful configurations for the logic cell 100b with two 1-bit ALUs 603 is less than 2⁵ (32). For this reason, a decoder circuit 900 which is represented in FIG. 8 is used, in which a decoder 902 is addressed with five configuration bit memory cells 300′, this decoder 902 having 25 output lines corresponding to the 25 configuration signals. Up to 2⁵ (32) configurations of the 25 configuration signals can be formed with the five configuration bit memory cells 300′, which is sufficient to enable the logic cell 300b to be universally used without restriction, as was already described. The logic cell 100b thus contains nine configuration bit memory cells in total, namely the four configuration bit memory cells of the block generator 604′ and the five configuration bit memory cells 300′ of the decoder circuit 900. Compared to the logic cell 100 according to prior art as shown in FIG. 1, which uses the LUT 201 with 16 configuration bit memory cells, this is 7 configuration bit memory cells fewer, the logic cell 100 in FIG. 1 not being configurable as two 1-bit ALUs with a total of two outputs, in contrast to the logic cell 100b. As a result of the lower number of configuration bit memory cells which have to be loaded for the configuration of the logic cell 100b, a configuration time is also advantageously correspondingly reduced.

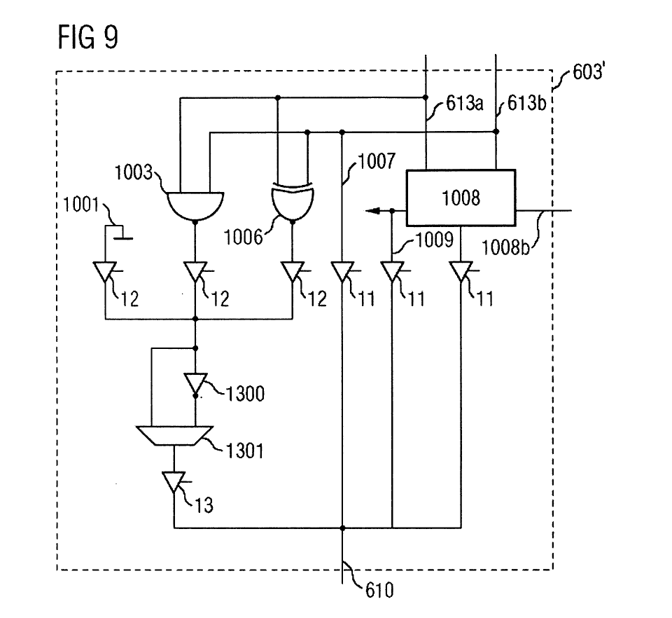

FIG. 9 represents a further embodiment for the 1-bit ALUs usable in the logic cell 100b. Compared to the 1-bit ALU 603 shown in FIG. 7, the 1-bit ALU 603′ lacks the logical 0 1002, the AND gate 1004 and the XOR gate 1005. As a substitute for these missing modules, the outputs of the NAND gate 1003 and of the XNOR gate 1006, and also the logical 1 1001, are each connected via a tri-state driver 12 to an input of a selection inversion logic 1300, 1301, this selection inversion logic 1300, 1301 being connected via a further tri-state driver 13 to the output 610 of the 1-bit ALU 603′. In order now to implement an AND function, an XOR function or a logical “0”, the corresponding tri-state driver 12 of the NAND gate 1003 or of the XNOR gate 1006, or the logical 1 1001, is switched through, and the selection inversion logic 1300, 1301 is configured to invert, the tri-state driver 13 likewise being switched through. The 1-bit ALU 603′ thus has the same functional range as the 1-bit ALU 603 shown in FIG. 7.

According to the invention there are also further possible implementations of the 1-bit ALUs that can be used in the logic cell 100b, if for example the NAND gate 1003 or the XNOR gate 1006 is replaced by an AND gate or an XOR gate respectively. The logical “1” 1001 could likewise be replaced by a logical “0”. It should also be pointed out that the full adder in the 1-bit ALU 603, 603′ only plays a part in the arithmetic mode of the logic cell 100b, where the carry-in input 1008b is used. In other words, the full adder is not needed in a configuration of the 1-bit ALU 603, 603′ as a look-up table, which is why in FIG. 9 it is also not connected to the selection inversion logic 1300, 1301 in the 1-bit ALU 603′.

The 1-bit ALU 603′ shown in FIG. 9 can incidentally be configured by seven configuration signals. Six configuration signals each control one of the three tri-state drivers 11 and one of the three tri-state drivers 12. The seventh configuration signal controls the multiplexer 1301, while the tri-state driver 13 is switched through precisely when one of the tri-state drivers 12 is switched through, and consequently it needs no configuration signal of its own. Nine configurations are naturally also meaningful for the 1-bit ALU 603′ shown in FIG. 9, as for the 1-bit ALU 603 shown in FIG. 7. For one thing, one of the six tri-state drivers 11, 12 can be switched through, giving six configurations, but in addition for each configuration in which one of the three tri-state drivers 12 is switched through, the selection inversion logic 1300, 1301 can be switched inverting or not inverting, giving three more configurations.

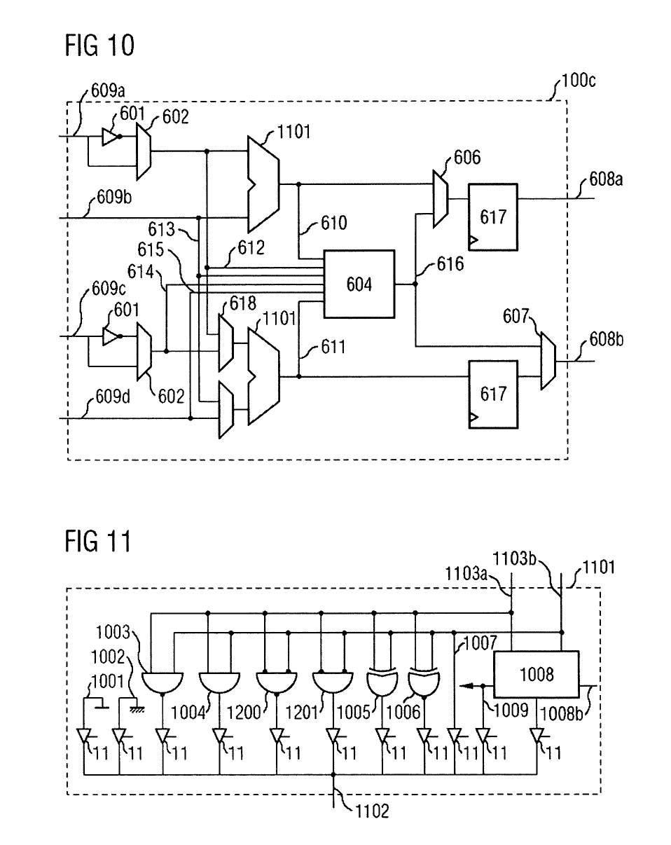

FIG. 10 shows a second embodiment of a logic cell 100c, which differs from the logic cell 100b shown in FIG. 4 only in the input area and in the 1-bit ALUs 1101 which are used. While for the logic cell 100b both inputs of both 1-bit ALUs 603 can be inverted with the respective selection inversion logic 601, 602, for the logic cell 100c shown in FIG. 10 only one input in each case of the two 1-bit ALUs 1101 can be inverted with the respective selection inversion logic 601, 602. The remaining reference labels correspond to those of the logic cell 100b in FIG. 4.

Since it is not possible for both inputs of the 1-bit ALU in the logic cell 100c to be inverted, a 1-bit ALU 1101 usable for the logic cell 100c must have a function other than that of the 1-bit ALU 603 or the 1-bit ALU 603′. The 1-bit ALU 1101 is represented in FIG. 11. In construction, the 1-bit ALU 1101 is similar to the 1-bit ALU 603 shown in FIG. 7, and for that reason only the differences are explained here. The 1-bit ALU 1101 additionally includes a NAND gate 1200 with inverted inputs and an AND gate 1201 with inverted inputs, the inputs of these two additional gates being connected to the inputs 1103a-b of the 1-bit ALU 1101. The outputs of the additional gates 1200, 1201 are each connected via a tri-state driver 11 to the output 1102 of the 1-bit ALU 1101.

An XOR gate or XNOR gate with inverted inputs is not needed for the 1-bit ALU 1101, since the function of an XOR gate or XNOR gate with inverted inputs is the same as the function of an XOR gate or XNOR gate respectively without inverted inputs.

For a synthesis tool, the logic cell 100c with the 1-bit ALUs 1101 offers no significant restriction compared to the logic cell 100b with the 1-bit ALUs 603 or 603′. In order for example to implement an AND function with the help of the logic cell 100c and the 1-bit ALU 1101, with one of two inputs inverted, the synthesis tool must connect the input to be inverted with the input 609a, which is fed via the selection inversion logic 601, 602 to the 1-bit ALU 1101, so that it is then possible by means of the selection inversion logic 601, 602 to invert the corresponding input, thereby implementing the required AND function with an inverted input.

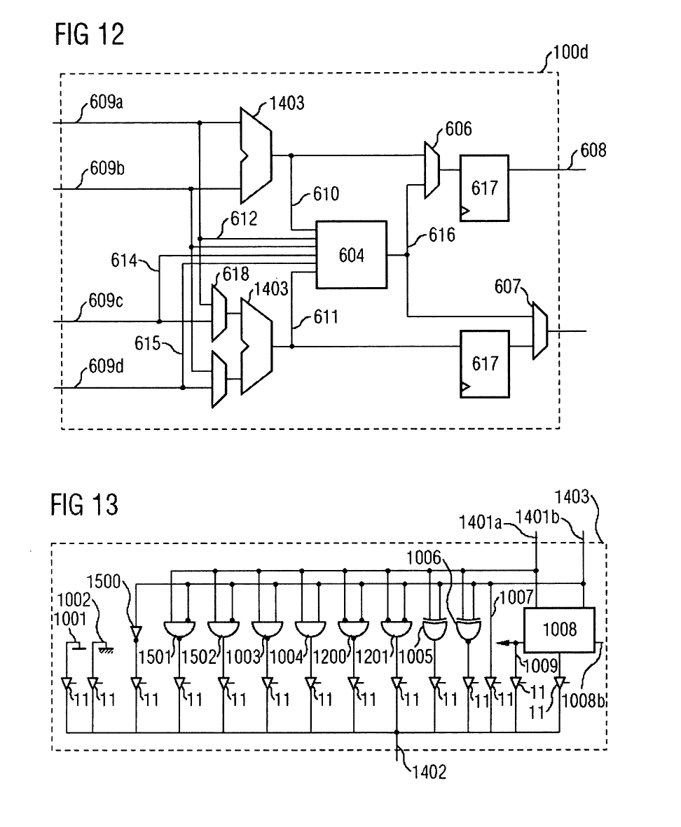

FIG. 12 represents a third embodiment of a logic cell 100d. None of the inputs 609a-d of the logic cell 100d can be inverted. Consequently none of the previously described 1-bit ALUs 603, 603′, 1101 can be used for the logic cell 100d. For this reason, a 1-bit ALU 1403 which is represented in FIG. 13 is used in the logic cell 100d.

Compared to the 1-bit ALU 1101, the 1-bit ALU 1403 additionally contains an inverter 1500, a NAND gate 1501 with an inverted input and an AND gate 1502 with an inverted input. The input of the inverter 1500 and the inverted input of the NAND gate 1501 and of the AND gate 1502 are connected to the same input 1401b of the 1-bit ALU 1403. The output of the inverter, the output of the NAND gate 1501 with inverted input and the output of the AND gate 1502 with inverted input is connected in each case via a tri-state driver 11 to the output 1402 of the 1-bit ALU. These three additional gates 1500-1502 replace the absent selection inversion logic in the logic cell 100d. An XOR gate or a XNOR gate with an inverted input is unnecessary, since an XOR gate or a XNOR gate with an inverted input has the same function as an XNOR gate or XOR gate respectively. Since the 1-bit ALU 1403 has 14 tri-state drivers 11, there are also 14 configuration signals and 14 meaningful configurations. Because of the omission of the selection inversion logics 601, 602, it is also true for the logic cell 100d that the number of meaningful configurations including the 1-bit ALU 1403 does not exceed 2⁵ (32).

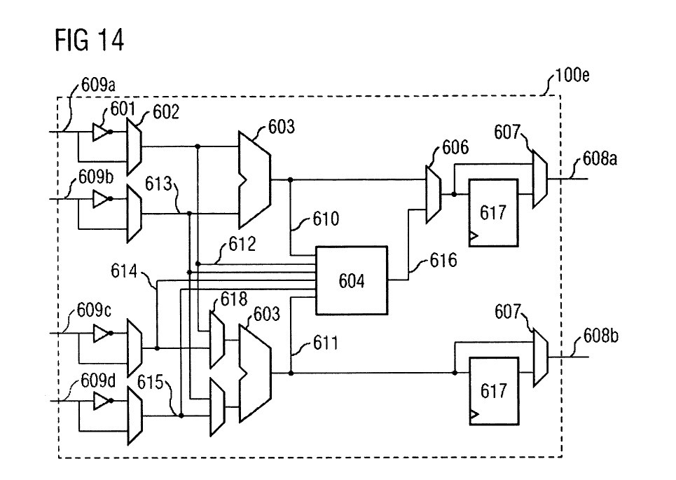

FIG. 14 represents a fourth embodiment of a logic cell 100e, which differs from the logic cell 100b in the output area only. In the logic cell 100e, a selector logic unit including a multiplexer 607 and a flip-flop 617 is preconnected to each output 608a-b of the logic cell 100e. The selector logic unit before the output 608a decides whether an output of the multiplexer 606 is connected directly or buffered via the flip-flop 617 to the output 608a. Similarly, the selector logic unit before the output 608b decides whether the output 611 of the second 1-bit ALU is connected directly or via the flip-flop 617 to the output 608b. Through buffering with the flip-flop 617, the corresponding output value is applied to the output of the logic cell unchanged over a clock period of a clock fed to the flip-flop 617, which is advantageous in a synchronous circuit design, for which the logic cell is used. In contrast to the logic cell 100b, the output 616 of the block generator 604 can only be connected to the output 608a of the logic cell 100e.

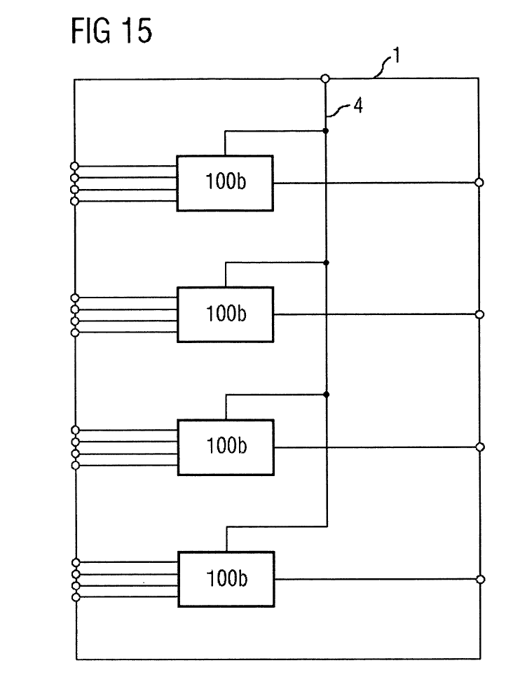

FIG. 15 shows a programmable logic array 1 with four logic cells 100b. Each of the four logic cells 100b is individually configurable via a configuration line 4. In the programmable logic array 1 the logic cells 100b are used exclusively in their function as look-up table (LUT), for which reason only one output of each logic cell 100b is connected to an output of the programmable logic array 1. Since each logic cell 100b is configured by nine configuration bit memory cells, as has previously been explained, the programmable logic array 1 is configured with 36 (4*9) configuration bits via the configuration line 4.

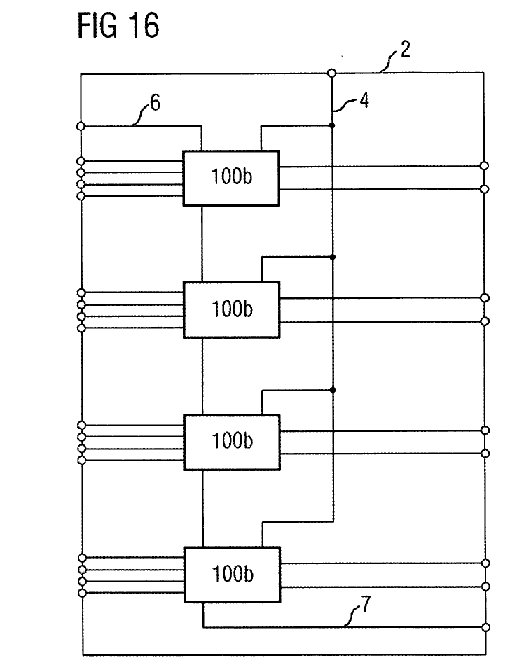

FIG. 16 represents a programmable arithmetic unit 2 with four logic cells 100b. These four logic cells 100b are operated exclusively in an arithmetic mode, for which reason the two outputs of each logic cell 100b are each connected to an output of the programmable arithmetic unit 2. A configuration of the logic cells 100b takes place via the configuration line 4. In order that arithmetic operations extending beyond the cell can also be carried out with the logic cell 100b, adjacent logic cells 100b are in each case connected together, on the one hand, with a carry-out output of the one logic cell being connected to a carry-in input of the other logic cell, and, on the other hand, the carry-in input of the first (top) logic cell is connected to a carry-in input 6 of the programmable arithmetic unit 2 and the carry-out output of the last (bottom) logic cell is connected to a carry-out output 7 of the programmable arithmetic unit 2.

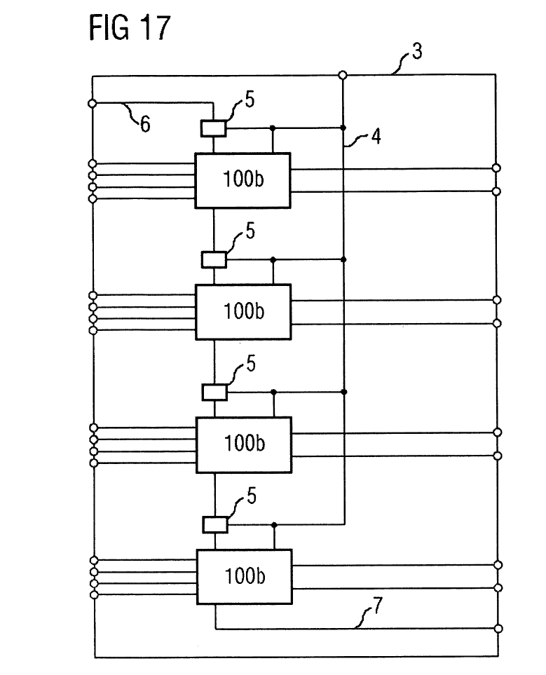

FIG. 17 represents a programmable digital circuit arrangement 3, which can be configured either as a programmable logic array or as a programmable arithmetic unit. The programmable digital circuit arrangement 3 can thus be configured such that it works either like the programmable logic array 1 or like the programmable arithmetic unit 2. For this reason both outputs of each logic cell 100b are also each connected to an output of the programmable digital circuit arrangement. Since two adjacent logic cells 100b in a configuration of the programmable digital circuit arrangement 3 as a programmable logic array may usually not influence each other, a selector logic unit 5 exists between each two adjacent logic cells 100b. In the configuration of the programmable digital circuit arrangement 3 as a programmable logic array, this selector logic unit 5 usually separates a connection between the carry-out output of the one logic cell and the carry-in input of the other logic cell. On the other hand, in the configuration of the programmable digital circuit arrangement as an inter-cell programmable arithmetic unit, the selector logic unit 5 connects the carry-out output of the one logic cell to the carry-in input of the other logic cell. For comparable reasons, the carry-in input of the first (top) logic cell is also connected via the selector logic unit 5 to a carry-in input 6 of the programmable digital circuit arrangement 3. The carry-out output of the last (bottom) logic cell is connected without the selector logic unit 5 to a carry-out output of the programmable digital circuit arrangement 3.

The present invention is preferably suitable for use with programmable logic circuits, in particular for use with FPGAs, PLDs (programmable logic devices) or PLAs (programmable logic arrays). However, it is not restricted to this preferred area of application, but can also be used, for example, with an at least partially cell-based circuit design, the logic cell according to the invention being used in particular as a special cell.

We claim:

1. A programmable logic cell comprising:
an output assuming a value being dependent on values of a plurality of inputs of the logic cell and on a Boolean function, the Boolean function determining for each setting of the inputs a Boolean value for the output; and
at least one arithmetic logic unit (ALU) and additional logic, the inputs of the logic cell being connected to inputs of the at least one ALU, the ALU having outputs where at least one output of the at least one ALU is connected via the additional logic to the output of the logic cell,
where the programmable logic cell is characterized by a Boolean function being configurable with the additional logic.

2. The programmable logic cell of claim 1, where the additional logic may be configured to provide a Boolean function corresponding with a number of parameters according to a number of inputs of the logic cell.

3. The programmable logic cell of claim 2, where the Boolean function corresponds to a Boolean function with the number of parameters, if a sequence order of the inputs can be predefined.

4. The programmable logic cell of claim 2, where the Boolean function corresponds to a Boolean function with the number of parameters, if the additional logic is configurable according to whether the additional logic inverts or does not invert at least one of the inputs.

5. The programmable logic cell of claim 3, where the Boolean function corresponds to a Boolean function with the number of parameters, if the additional logic is configurable according to whether the additional logic inverts or does not invert at least one of the inputs.

6. The programmable logic cell of claim 1, where the logic cell comprises four inputs, that the at least one ALU comprises two 1-bit ALUs, and where in each case two of the four inputs are connected on the input side to one of the two 1-bit ALUs.

7. The programmable logic cell of claim 6, where at least one of the two 1-bit ALUs is configured with an output assuming a value of a further Boolean function dependent on the two inputs of the at least one 1-bit ALU, and where the at least one of the two 1-bit ALUs is configurable via the additional logic in such a way that the further Boolean function can be a Boolean function having two parameters.

8. The programmable logic cell of claim 7, where the at least one of the two 1-bit ALU is configured such that the further Boolean function can be a Boolean function with two parameters, if a sequence order of the two inputs can be predefined.

9. The programmable logic cell of claim 7, where at least one of the two inputs of the at least one 1-bit ALU), being configurably inverted or not inverted by the additional logic is configured to be fed to the at least one 1-bit ALU.

10. The programmable logic cell of claim 8, where at least one of the two inputs of the at least one 1-bit ALU being configurably inverted or not inverted by the additional logic is configured to be fed to the at least one 1-bit ALU.

11. The programmable logic cell of claim 6, where at least one of the two 1-bit ALUs includes a full adder, an XNOR gate an XOR gate, an AND gate and a NAND gate, each being connected on the input side to the two inputs of the at least one 1-bit ALU and on the output side in each case over a tri-state driver to the output of the at least one 1-bit ALU, where a logical 1, a logical 0 and one of the two inputs of the at least one 1-bit ALU additionally being connected over a tri-state driver in each case to the output of the at least one 1-bit ALU, and where via the additional logic, only one of the tri-state drivers being switched through and all others being switched to a high resistance.

12. The programmable logic cell of claim 11, where the at least one 1-bit ALU further includes an input-side inverted AND gate and an input-side inverted NAND gate, each being connected on the input side to the two inputs of the at least one 1-bit ALU and on the output side in each case over a tri-state driver to the output of the at least one 1-bit ALU, and where via the additional logic only one of the tri-state drivers of the at least one 1-bit ALU being switched through, and others being switched to a high resistance.

13. The programmable logic cell of claim 12, where the at least one 1-bit ALU further includes an AND gate inverted on an input and a NAND gate inverted on an input, each being connected on the input side to the two inputs of the at least one 1-bit ALU and on the output side in each case over a tri-state driver to the output of the at least one 1-bit ALU, one of the two inputs of the at least one 1-bit ALU being inverted in each case over a tri-state driver additionally being connected to the output of the at least one 1-bit ALU, and where, via the additional logic, only one of the tri-state drivers of the at least one 1-bit ALU being switched through, and others being switched to a high resistance.

14. The programmable logic cell of claim 6, where at least one of the two 1-bit ALUs includes a full adder, an XNOR gate and a NAND gate each being connected on the input side to the two inputs of the at least one 1-bit ALU, the XNOR gate and the NAND gate being connected on the output side together with a logical 1 over a tri-state driver in each case on the input side to a selection inversion logic, an input of the selection inversion logic being configurable either inverted or not inverted is switched through to an output of the selection inversion logic, where the full adder, one of the two inputs of the at least one 1-bit ALU and the selection inversion logic are connected in each case over a tri-state driver to the output of the at least one 1-bit ALU, and where via the additional logic at most one of the tri-state drivers connected input-side to the selection inversion logic and only one of the tri-state drivers connected to the output of the at least one 1-bit ALU are switched through and all other tri-state drivers are switched to a high resistance, the tri-state driver connected on the output side to the selection inversion logic being switched through if one of the tri-state drivers connected input-side to the selection inversion logic is switched through via the additional logic.

15. The programmable logic cell of claim 6, where the additional logic for at least one input of the logic cell comprises a selection inversion logic in each case, the selection inversion logic being configurable by the additional logic to invert or not invert the corresponding input.

16. The programmable logic cell of claim 6, where the additional logic includes a circuit unit having at most eight configuration bit memory cells where, dependent on the four inputs of the logic cell, the circuit unit switches through either a value of one of the at most eight configuration bit memory cells or an output of the two 1-bit ALUs to the output of the switching unit (604, 604′), the output of the switching unit being connected to the output of the logic cell.

17. The programmable logic cell of claim 16, where the circuit unit includes four configuration bit memory cells (300).

18. The programmable logic cell of claim 16, where the logic cell includes two outputs, the additional logic being arranged to configure whether in each case one of the outputs of the two 1-bit ALUs is connected to one of the two outputs of the logic cell or whether the output of the circuit unit is connected to one of the outputs.

19. The programmable logic cell of claim 18, where if the additional logic is configured such that in each case one of the outputs of the two 1-bit ALUs is connected to one of the two outputs of the logic cell, the values of the configuration bit memory cells of the circuit unit configure the logic cell.

20. The programmable logic cell of claim 16, where configurations of the logic cell are not influenced by the configuration bit memory cells of the circuit unit.

21. The programmable logic cell of claim 1, where at least one output of the logic cell is equipped with an output logic that includes a clocked memory element, to which a system clock can be fed, so that the value of the corresponding output of the logic cell is fixed for a system clock period.

22. The programmable logic cell of claim 1, where at least one output of the logic cell is equipped with an output logic including a clocked memory element to which the system clock can be fed, and a selector logic unit, the selector logic unit being developed in such a way that either the value of the corresponding output of the logic cell reaches the corresponding output of the logic cell directly or via the clocked memory element.

23. The programmable logic cell of claim 6, where the additional logic includes a decoder circuit being configured such that configuration bit memory cells cause configurations of the additional logic, and that a number of the configuration bit memory cells A_{KBL} satisfies the following equation
A_{KBL}=2 to the power A_{KON},
where A_{KON} is the number of configurations of the additional logic that can be tapped at the output of the decoder circuit.

24. The programmable logic cell of claim 6, where for at least one of the two 1-bit ALUs it can be configured via the additional logic whether it is connected on the input side to the two inputs assigned to it or to the two inputs assigned to the respective other 1-bit ALU.

25. A programmable logic cell comprising:
at least one logic cell with an output assuming a value being dependent on values of a plurality of inputs of the logic cell and on a Boolean function, the Boolean function determining for each setting of the inputs a Boolean value for the output, the at least one logic cell further including at least one arithmetic logic unit (ALU) and additional logic, the inputs of the logic cell being connected to inputs of the at least one ALU, the ALU having outputs where at least one output of the at least one ALU is connected via the additional logic to the output of the logic cell,
where the programmable logic cell is characterized by a Boolean function being configurable with the additional logic.

26. A programmable arithmetic unit, comprising
at least one logic cell with an output assuming a value being dependent on values of a plurality of inputs of the logic cell and on a Boolean function, the Boolean function determining for each setting of the inputs a Boolean value for the output, the at least one logic cell further including at least one arithmetic logic unit (ALU) and additional logic, the inputs of the logic cell being connected to inputs of the at least one ALU, the ALU having outputs where at least one output of the at least one ALU is connected via the additional logic to the output of the logic cell,
where the programmable logic cell is characterized by a Boolean function being configurable with the additional logic.

27. A programmable digital circuit arrangement, which is configurable as a programmable logic array or as a programmable arithmetic unit, comprising
at least one logic cell with an output assuming a value being dependent on values of a plurality of inputs of the logic cell and on a Boolean function, the Boolean function determining for each setting of the inputs a Boolean value for the output, the at least one logic cell further including at least one arithmetic logic unit (ALU) and additional logic, the inputs of the logic cell being connected to inputs of the at least one ALU, the ALU having outputs where at least one output of the at least one ALU is connected via the additional logic to the output of the logic cell,
where the programmable logic cell is characterized by a Boolean function being configurable with the additional logic.

28. A programmable logic cell, comprising:
means for receiving input;
means for setting values based on the input;
means for generating an output value being dependent on values of the input and on a logical function, the logical function determining an output value for each setting of the inputs;
means for performing arithmetic logic computations; and
logic means for configuring the logical function.

29. The programmable logic cell of claim 28, further comprising configuration means to replicate any desired Boolean function with four parameters.

30. The programmable logic cell of claim 28, further comprising configuration means to replicate any desired Boolean function with any two Boolean functions with two parameters.
